(19) United States
(12) Patent Application Publication
(10) Pub. No.: US 2024/0224539 A1
(43) Pub. Date: Jul. 4, 2024

(54) FERROELECTRIC-RAM WITH INTEGRATED DOMAIN REVERSAL CATALYST

(71) Applicant: International Business Machines Corporation, Armonk, NY (US)

(72) Inventors: Julien Frougier, Albany, NY (US); Ruilong Xie, Niskayuna, NY (US); Min Gyu Sung, Latham, NY (US); Chanro Park, Clifton Park, NY (US); Juntao Li, Cohoes, NY (US); Alexander Reznicek, Troy, NY (US)

(21) Appl. No.: 18/089,670

(22) Filed: Dec. 28, 2022

(51) Int. Cl. H10B 53/30; G11C 11/22; H01L 21/28

(52) U.S. Cl. CPC H10B 53/30; G11C 11/221; H01L 28/60; H01L 29/40111

(57) ABSTRACT

A ferroelectric random access memory cell comprises a ferroelectric active layer comprising a first ferroelectric material and at least one second ferroelectric material in contact with the first ferroelectric material; a first electrode in contact with the first ferroelectric material and the second ferroelectric material, the first electrode being positioned at a first side of the ferroelectric active layer; and a second electrode in contact with the first ferroelectric material and the second ferroelectric material, the second ferroelectric material being positioned at a second opposing side of the ferroelectric active layer. The first ferroelectric material has a threshold electric field for an intrinsic electric polarization reversal that is higher than the threshold electric field for an intrinsic electric polarization reversal of the second ferroelectric material. The first ferroelectric material at least partially surrounds the second ferroelectric material.

### BACKGROUND

The exemplary embodiments described herein relate generally to memory devices and their manufacture and, more specifically, to the manufacture of random access memory structures using ferroelectric materials.

Ferroelectric materials are known to exhibit unique characteristics as compared to non-ferroelectric materials. In particular, ferroelectric materials exhibit the ability to maintain a spontaneous electric polarization inherent to the crystal structure upon an application of an electric field. This polarization does not disappear even when the electric field is removed. The spontaneous polarization of ferroelectric materials implies a hysteresis effect which can be used as a memory function. For example, ferroelectric capacitors may be used in the manufacture of ferroelectric random access memory (FeRAM or FRAM).

In the application of an external electric field to a ferroelectric material, the applied electric field moves the center atom in the crystal structure in the direction of the field. The center atom will remain in the off-centered position even after the applied electric field is removed. The position of the off-centered “central” atom then affects the voltage which is used to determine whether it represents a “0” or a “1.”

A typical architecture in a FeRAM cell provides random access memory similar in construction to that of a dynamic random access memory (DRAM) cell. A capacitor having a FeRAM cell uses a ferroelectric layer as an active memory layer positioned between top and bottom electrodes, the ferroelectric layer being used instead of a dielectric layer (as in DRAM) in order to achieve non-volatility. Using a ferroelectric layer provides for short programming time, lower power usage, and may operate as a possible alternative to flash memory.

However, in FeRAM cells using the ferroelectric material, the active memory layer is formed by multiple ferroelectric domains, and during the switching process of the memory cell the domain reversal may be initiated randomly by nucleation, for example, from a defect or a sidewall. The reversal is then propagated through the ferroelectric layer until all the domains are reversed in the new stable state. This randomness during the switching initialization can introduce variability of the switching speed-time for every cycle depending on where the nucleation physically initiates (for example, in the center versus the periphery of the cell).

### BRIEF SUMMARY

In one exemplary aspect, a ferroelectric random access memory cell comprises a ferroelectric active layer comprising a first ferroelectric material and at least one second ferroelectric material in contact with the first ferroelectric material; a first electrode in contact with the first ferroelectric material and the second ferroelectric the material, first electrode being positioned at a first side of the ferroelectric active layer; and a second electrode in contact with the first ferroelectric material and the second ferroelectric material, the second ferroelectric material being positioned at a second opposing side of the ferroelectric active layer. The first ferroelectric material has a threshold electric field for an intrinsic electric polarization reversal that is higher than the threshold electric field for an intrinsic electric polarization reversal of the second ferroelectric material. The first ferroelectric material at least partially surrounds the second ferroelectric material.

In another exemplary aspect, a ferroelectric random access memory cell comprises an active layer comprising a ferroelectric material having a concentration gradient with regard to at least one element in the active layer; and a first electrode and a second electrode in contact with the ferroelectric material, the first electrode being positioned at a first side of the active layer and the second electrode being positioned at a second side of the active layer. A first portion of the ferroelectric material has a threshold electric field for an intrinsic electric polarization reversal that is higher than a threshold electric field for an intrinsic electric polarization reversal of a second portion of the ferroelectric material.

In another exemplary aspect, a method of forming a ferroelectric random access memory cell comprises forming a bottom electrode on a device layer; depositing a first ferroelectric material on the bottom depositing electrode; a second ferroelectric material within the first ferroelectric material; and forming a top electrode on the first ferroelectric material and the second ferroelectric material. The first ferroelectric material has a higher threshold electric field value for an intrinsic electric polarization reversal than the second ferroelectric material.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 is a schematic perspective view of one example embodiment of a FeRAM cell between two electrodes;

FIG. 2 is a schematic diagram of the FeRAM cell of FIG. 1;

FIGS. 3A through 3G are schematic side views of an example structure incorporating the FeRAM cell and an example of fabrication steps of the FeRAM cell using a two mask process;

FIG. 3H is a flow diagram illustrating the example fabrication of FIGS. 3A through 3G;

FIGS. 4A through 4D are schematic side views of an example of a fabrication of a FeRAM cell using a one mask process;

FIG. 4E is a flow diagram illustrating the example fabrication of FIGS. 4A through 4D;

FIGS. 5A through 5F are schematic side views of an example of a fabrication of a FeRAM cell using a one mask process with scaled dimension;

FIG. 5G is a flow diagram illustrating the example fabrication of FIGS. 5A through 5F;

FIGS. 6A through 6E are schematic side views of examples of fabrications of FeRAM cells using composition grading of a ferroelectric material;

FIG. 6F is a flow diagram illustrating the example fabrication of FIGS. 6A through 6E;

FIG. 7 is a graphical representation of different operating (polarization) states of the ferroelectric cell; and

FIG. 8 is an example circuit used for the write operations of FIG. 7.

### DETAILED DESCRIPTION

The words “exemplary” and “example” are used herein to mean “serving as an example, instance, or illustration.” Any embodiment described herein as “exemplary” or “example” is not necessarily to be construed as preferred or advantageous over other embodiments. All of the embodiments described in this Detailed Description are exemplary or example embodiments provided to enable persons skilled in the art to make or use the invention and not to limit the scope of the invention which is defined by the claims.

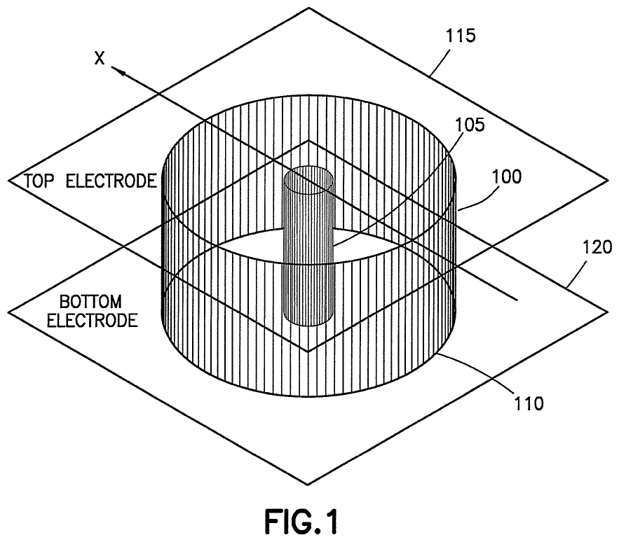

The exemplary embodiments described herein are directed to FeRAM cells. Referring to FIG. 1, one example of a FeRAM cell is shown generally at 100 and is hereinafter referred to as “FeRAM cell 100.” FeRAM cell 100 includes a first ferroelectric material 110 at least partially surrounding a second ferroelectric material 105. The second ferroelectric material 105 allows for the application of a low-threshold electric field (Eth2) for intrinsic electric polarization reversal that provides for a reversal of polarization. The role of the second ferroelectric material 105 is essentially that of a domain reversal catalyst. The first ferroelectric material 110 allows for the application of a high-threshold electric field (Eth1) for intrinsic electric polarization reversal that provides for data retention of the cell. The FeRAM cell 100 is sandwiched between a top electrode 115 and a bottom electrode 120.

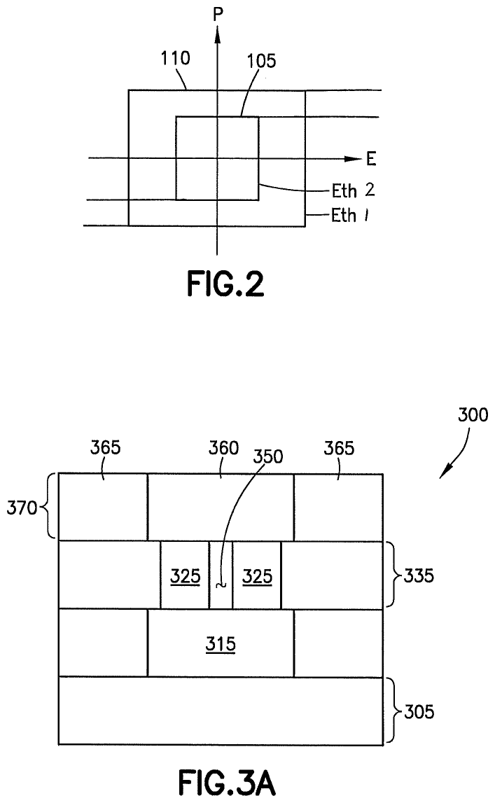

Referring to FIG. 2, a schematic representation of the FeRAM cell 100 shows polarization-electric field characteristics. As shown, the second ferroelectric material 105 is enclosed by the first ferroelectric material 110. In operation, a voltage is applied across the top electrode 115 and the bottom electrode 120 to power the cell 100, and the domains in the centrally-located second ferroelectric material 105 switch before the domains in the first ferroelectric material 110 and provide nucleation points for reversal of the domains in the first ferroelectric material 110. The polarization reversal dynamic starts systematically from the center and propagates to the edges of the cell with a radial symmetry.

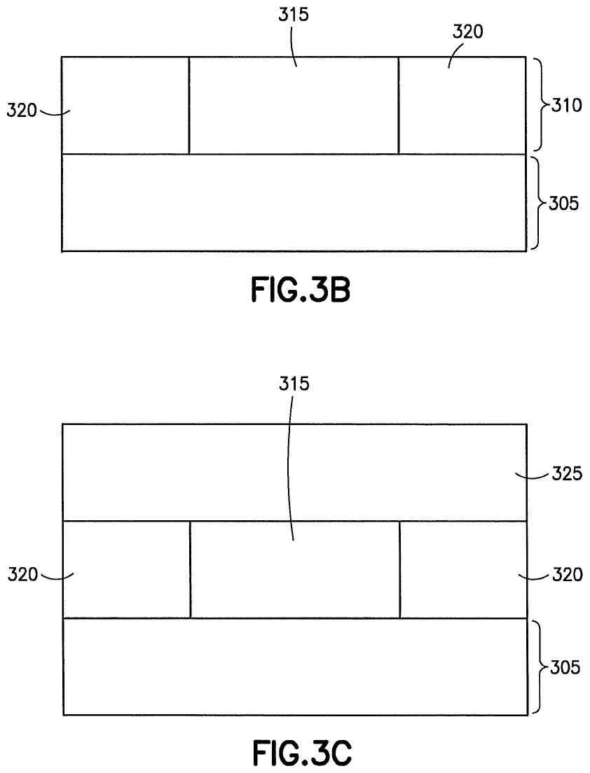

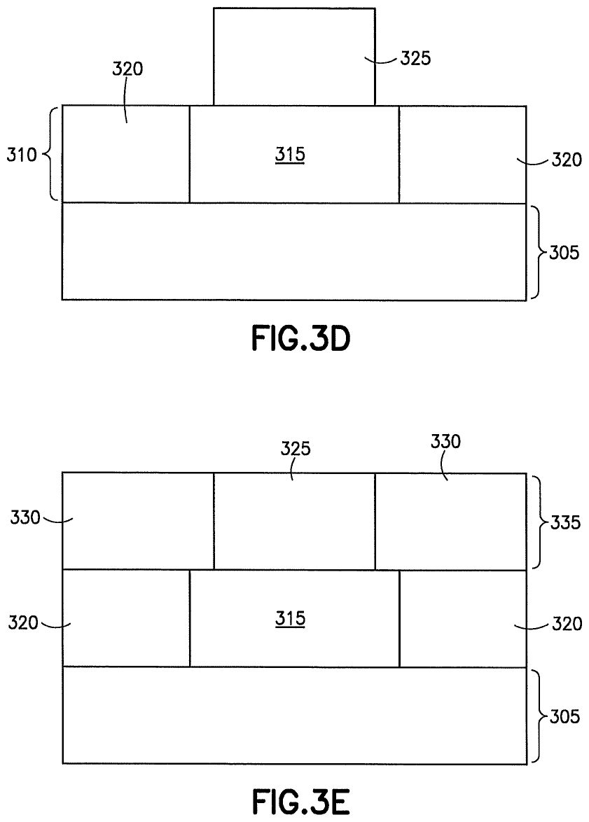

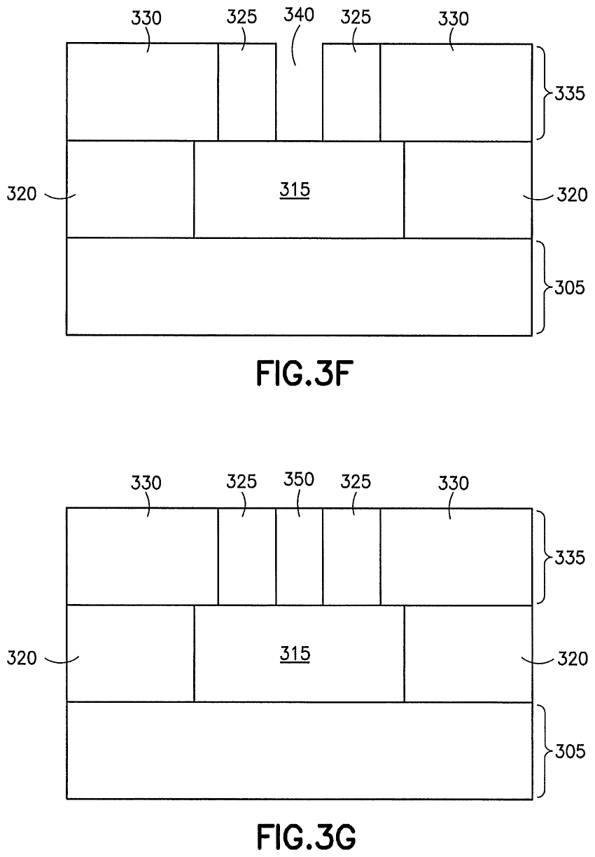

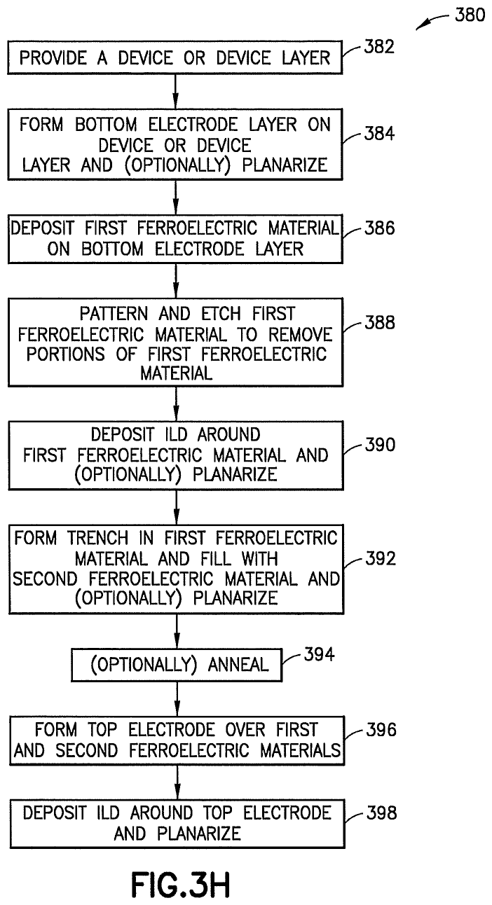

Referring now to FIG. 3A through 3G, one example of a FeRAM structure incorporating a FeRAM cell 100 having a domain reversal catalyst and a method of fabricating such a structure is shown. FIG. 3A shows the FeRAM structure at 300. The method of fabrication uses two masks. As shown in FIG. 3B, a device or device layer 305 is provided on which a bottom electrode layer 310 is formed. The bottom electrode layer 310 includes a bottom electrode 315 and a first interlayer dielectric 320 (first ILD 320) alongside the bottom electrode 315. The bottom electrode 315 and the first ILD 320 may be deposited or formed on the device layer 305 using any suitable technique. Planarization of an upper surface of the formed bottom electrode layer 310 may be carried out as needed.

As shown in FIG. 3C, a first ferroelectric material 325 is deposited on the upper surface of the bottom electrode layer 310. In particular, the first ferroelectric material 325 is deposited on the upper surfaces of the bottom electrode 315 and the first ILD 320. The first ferroelectric material 325 may be, for example, Pb(Zr, Ti)O₃, BiFeO₃, BaTiO₃, and/or doped-hafnium oxide (s) (doped with, for example, zirconium oxides, yttrium, silicon, aluminum, and/or lanthanum) and may be deposited using any suitable technique including, but not limited to, chemical vapor deposition (CVD), physical vapor deposition (PVD), plasma enhanced chemical vapor deposition (PECVD), atomic layer deposition (ALD), or the like.

As shown in FIG. 3D, the first ferroelectric material 325 is patterned and etched such that the first ferroelectric material 325 is positioned on the upper surface of the bottom electrode 315 and such that the first ILD 320 is exposed.

As shown in FIG. 3E, a second ILD 330 is deposited around the first ferroelectric material 325 to form a ferroelectric material layer 335. Planarization of an upper surface of the ferroelectric material layer 335 may be carried out as needed (for example, using chemical mechanical polish (CMP)).

As shown in FIG. 3F, a hole or trench 340 is patterned and cut, etched, or otherwise formed in the first ferroelectric material 325. One manner by which the trench 340 may be formed is reactive ion etching (RIE).

As shown in FIG. 3G, the trench 340 is filled with a second ferroelectric material 350 such that the second ferroelectric material 350 is in contact with the first ferroelectric material 325 on opposing sides of the second ferroelectric material 350. The first ferroelectric material 325 and the second ferroelectric material 350 may be any type of ferroelectric materials as long as Eth1 is greater than Eth2. The second ferroelectric material 350 may be deposited using any suitable technique. Planarization of upper surfaces of the ferroelectric material layer 335 may be carried out as needed (for example, using CMP). In some embodiments, if the first ferroelectric material 325 and the second ferroelectric material 350 are amorphous, a recrystallization anneal step may be carried out to facilitate the creation of a high-quality interface between the two ferroelectric materials formed by a juxtaposition of grain boundaries from the first ferroelectric material 325 and the second ferroelectric material 350.

Referring back to FIG. 3A, a top electrode 360 is deposited on the first ferroelectric material 325 and the second ferroelectric material 350. An upper ILD 365 is deposited or formed around the top electrode 360 to form a top electrode layer 370. Planarization of an upper surface of the top electrode layer 370 may be carried out as needed.

Referring now to FIG. 3H, a flow showing one example method of fabricating the FeRAM structure 300 of FIGS. 3A through 3G is shown at 380 and is hereinafter referred to as “method 380.” In method 380, a device or device layer is provided as indicated at step 382. A bottom electrode layer is then formed on the device or device layer as indicated at step 384. Planarization (for example, CMP) may be carried out. As indicated at step 386, a first ferroelectric material is deposited on the bottom electrode layer. As indicated at step 388, the first ferroelectric material is patterned, and etching is carried out to remove portions of the first ferroelectric material. An ILD is then deposited around the first ferroelectric as material, indicated at step 390. Planarization may be carried out. As indicated at step 392, a trench is formed in the first ferroelectric material and filled with a second ferroelectric material (with optional planarization). As indicated at step 394, an anneal step may be carried out if the first ferroelectric material and the second ferroelectric material are amorphous, to facilitate the creation of a high-quality interface between the two ferroelectric materials. As indicated at step 396, a top electrode is formed over the ferroelectric materials. As indicated at step 398, another ILD may be formed around the top electrode, and a planarization may be carried out.

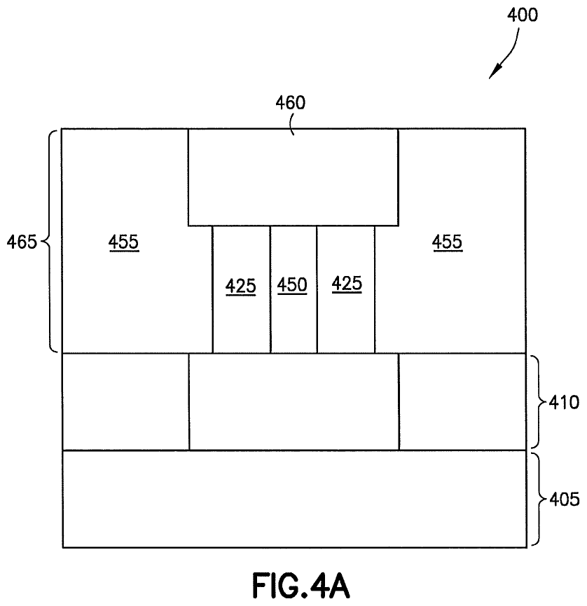

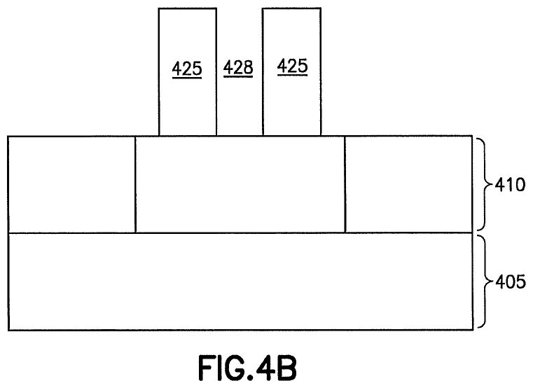

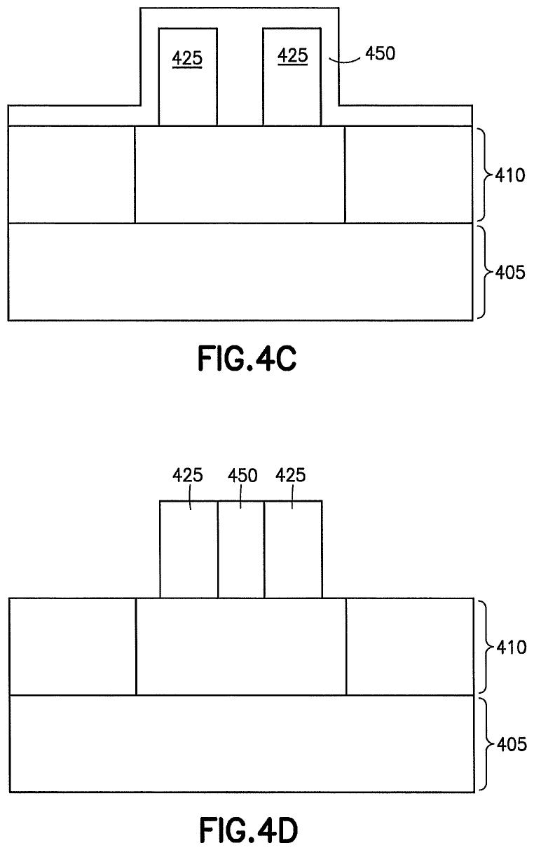

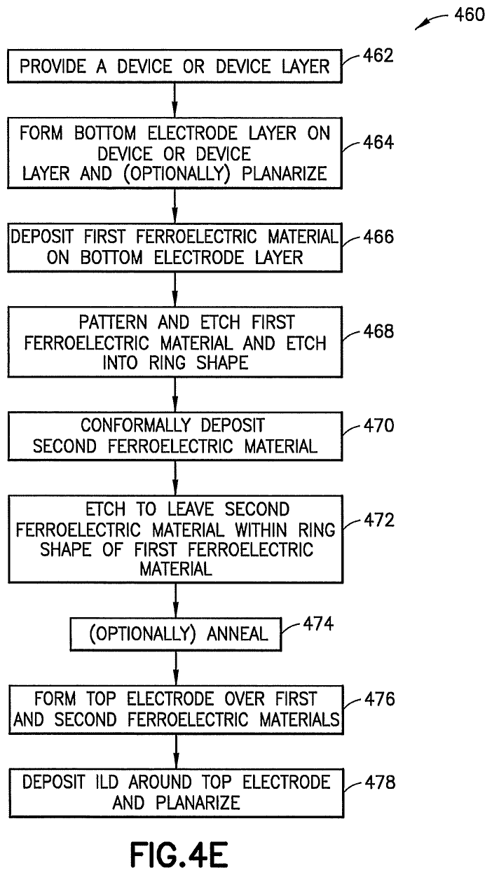

Referring now to FIGS. 4A through 4D, another example of a FeRAM structure incorporating a FeRAM cell 100 and a method of fabricating such a structure is shown. FIG. 4A shows the FeRAM structure at 400. The method of fabrication uses one mask. In this example method, a device or device layer 405 is provided and a bottom electrode layer 410 and a first ferroelectric material 425 are deposited as in the previous example method. As shown in FIG. 4B, however, the first ferroelectric material 425 is masked, patterned, and etched into a ring shape with the first ferroelectric material 425 defining a wall with an open center portion 428.

As shown in FIG. 4C, a second ferroelectric material 450 is conformally deposited onto the upper surfaces of the bottom electrode layer 410 and onto the sides and top of the ring shape of the first ferroelectric material 425. The open center portion 428 is filled with the second ferroelectric material 450, which allows for the application of the low-threshold electric field (Eth2) for intrinsic electric polarization reversal.

As shown in FIG. 4D, the second ferroelectric material 450 is isotropically etched back such that the second ferroelectric material 450 remains only in the open center portion 428 within the wall defined by the ring shape of the first ferroelectric material 425. In some embodiments, if the first ferroelectric material 425 and the second ferroelectric material 450 are amorphous, a recrystallization anneal step may be carried out to facilitate the creation of a high-quality interface between the two ferroelectric materials formed by a juxtaposition of grain boundaries from the first ferroelectric material 425 and the second ferroelectric material 450.

Referring back to FIG. 4A, a top electrode 460 is deposited on the first ferroelectric material 425 and the second ferroelectric material 450. An upper ILD 455 is deposited or formed around the top electrode 460 to form a top electrode layer 465. Planarization of an upper surface of the top electrode layer 465 may be carried out as needed.

Referring now to FIG. 4E, a flow showing one example method of fabricating the FeRAM structure 400 of FIGS. 4A through 4D is shown at 460 and is hereinafter referred to as “method 460.” In method 460, a device or device layer is provided as indicated at step 462. A bottom electrode layer is then formed on the device or device layer as indicated at step 464. Planarization (for example, CMP) may be carried out. As indicated at step 466, a first ferroelectric material is deposited on the bottom electrode layer. As indicated at step 468, the first ferroelectric material is patterned, and etching is carried out to remove portions of the first ferroelectric material to form the first ferroelectric material into a ring shape. A second ferroelectric material is then conformally deposited onto the bottom electrode layer and onto the first ferroelectric material, as indicated at step 470. The second ferroelectric material is isotropically etched back such that the second ferroelectric material remains within the ring shape of the first ferroelectric material, as indicated at step 472. As indicated at step 474, an anneal step may be carried the first ferroelectric material and the second out if ferroelectric material are amorphous, to facilitate the creation of a high-quality interface between the two ferroelectric materials. As indicated at step 476, a top electrode is formed over the ferroelectric materials. As indicated at step 478, an ILD may be formed around the top electrode, and a planarization may be carried out.

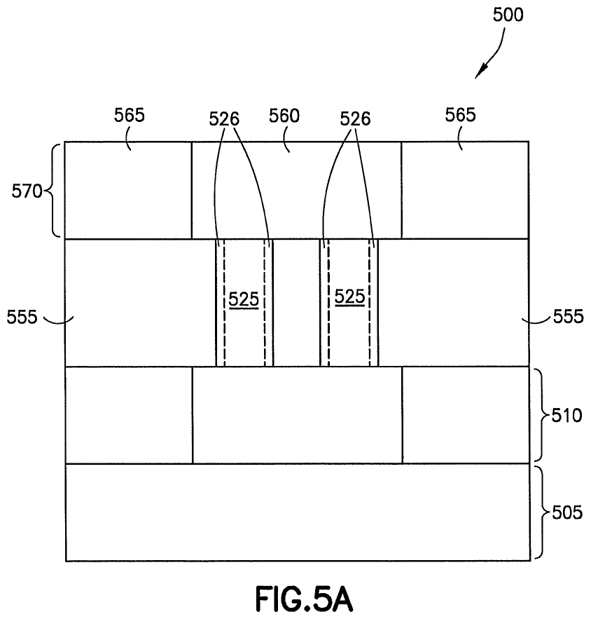

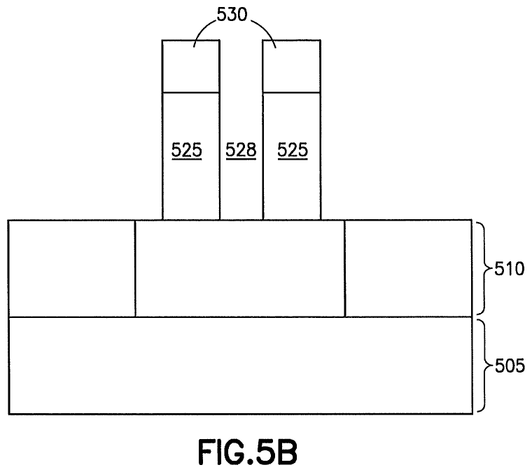

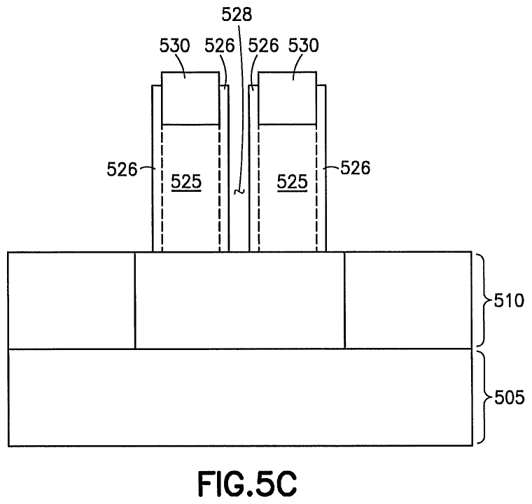

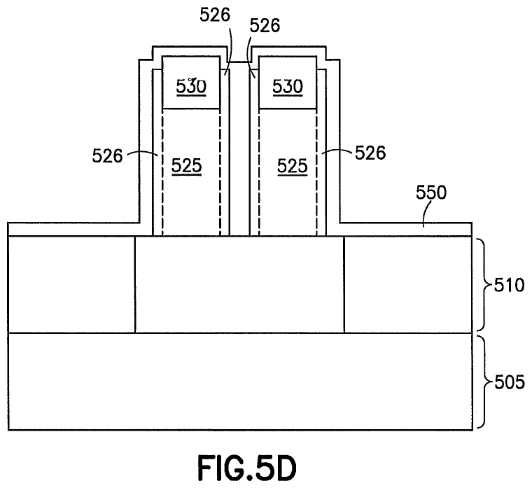

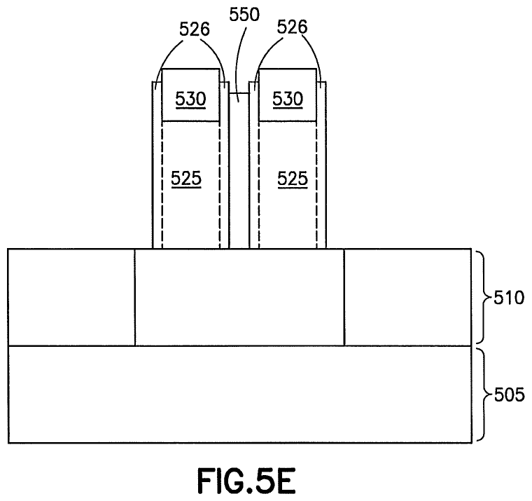

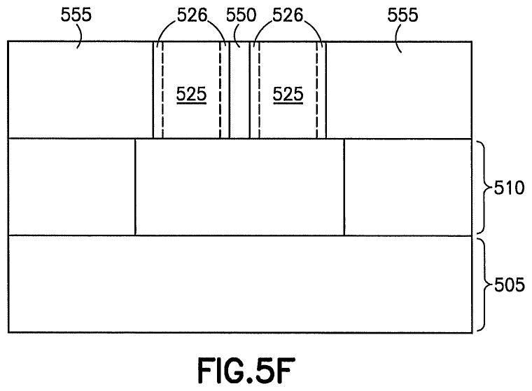

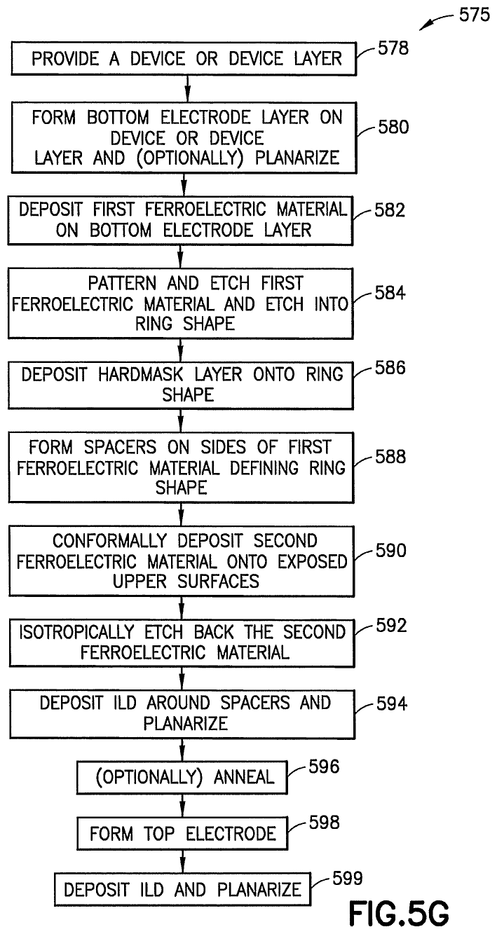

Referring now to FIGS. 5A through 5F, another example of a FeRAM structure incorporating a FeRAM cell 100 and a method of fabricating such a structure is shown. FIG. 5A shows the structure at 500. The method of fabrication uses one mask with a scaled dimension. In this example method, a device or device layer 505 is provided and a bottom electrode layer 510 and a first ferroelectric material 525 are deposited as in previous example methods. As shown in FIG. 5B, however, the first ferroelectric material 525 is masked and patterned into a ring shape with the first ferroelectric material 525 defining a wall with an open center portion 528 and a hardmask layer 530 deposited on an upper surface of the wall.

As shown in FIG. 5C, additional amounts of the first ferroelectric material 525 are deposited to form spacers 526 adjacent to the wall of the ring structure. The spacers 526 are formed on both the inside and outside of the wall. Forming the spacers 526 on the outside of the wall extends the diameter of the ring structure, and forming the spacers 526 in the inside of the wall shrinks the cross dimension of the open center portion 528. The deposited first ferroelectric material 525 forming the spacers 526 may cover at least part of the exposed sides of the hardmask layer 530.

As shown in FIG. 5D, a second ferroelectric material 550 (which allows for the application of the low-threshold electric field (Eth2) for instrinsic electric polarization reversal) is conformally deposited onto the upper surfaces of the bottom electrode layer 510 and onto the sides and top of the ring shape of the first ferroelectric material 525 (also conformally covering the exposed hardmask layer 530). The open center portion 528 is also filled with the second ferroelectric material 550.

As shown in FIG. 5E, the second ferroelectric material 550 is isotropically etched back and removed such that the second ferroelectric material 550 remains only in the open center portion 528 within the wall defined by the ring structure.

As shown in FIG. 5F, an ILD 555 is deposited around the spacers 526 on the outer sides of the wall defining the ring structure. A CMP is carried out on the exposed upper surfaces. In some embodiments, if the first ferroelectric material 525 and the second ferroelectric material 550 are amorphous, a recrystallization anneal step may be carried out to facilitate the creation of a high-quality interface between the two ferroelectric materials formed by a juxtaposition of grain boundaries from the first ferroelectric material 525 and the second ferroelectric material 550.

Referring back to FIG. 5A, a top electrode 560 is deposited on the first ferroelectric material 525 and the second ferroelectric material 550. An upper ILD 565 is deposited or formed around the top electrode 560 to form a top electrode layer 570. Planarization of an upper surface of the top electrode layer 570 may be carried out as needed.

Referring now to FIG. 5G, a flow showing one example method of fabricating the FeRAM structure 500 of FIGS. 5A through 5F is shown at 575 and is hereinafter referred to as “method 575.” In method 575, a device or device layer is provided as indicated at step 578. A bottom electrode layer is then formed on the device or device layer as indicated at step 580. Planarization (for example, CMP) may be carried out. As indicated at step 582, a first ferroelectric material is deposited on the bottom electrode layer. As indicated at step 584, the first ferroelectric material is patterned, and etching is carried out to remove portions of the first ferroelectric material to form the first ferroelectric material into a ring shape. As indicated at step 586, a hardmask layer is deposited onto the upper surface of the ring shape. Spacers comprising the first ferroelectric material are then formed on the sides of the first ferroelectric material, as indicated at step 588. A second ferroelectric material is conformally deposited onto the ring shape, spacers, hardmask, and bottom electrode layer, as indicated at step 590. As indicated at step 592, the second ferroelectric material is isotropically etched back. As indicated at step 594, an ILD is deposited adjacent to the spacers and planarization (for example, CMP) is carried out as necessary. As indicated at step 596, an anneal step may be carried out if the first ferroelectric material and the second ferroelectric material are amorphous, to facilitate the creation of a high-quality interface between the two ferroelectric materials. As indicated at step 598, a top electrode is formed over the ferroelectric materials. As indicated at step 599, an ILD may be formed around the top electrode, and a planarization may be carried out.

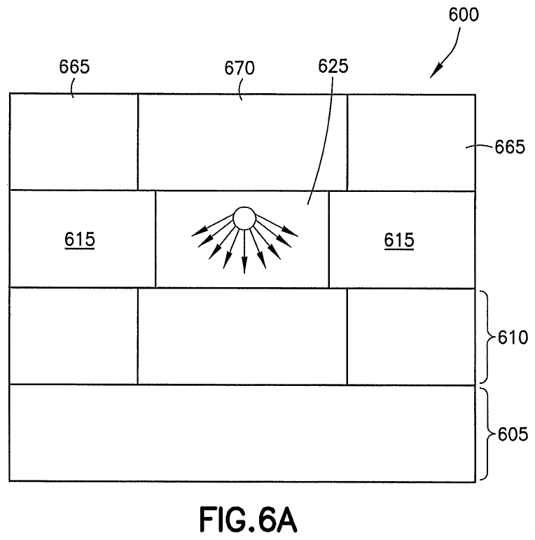

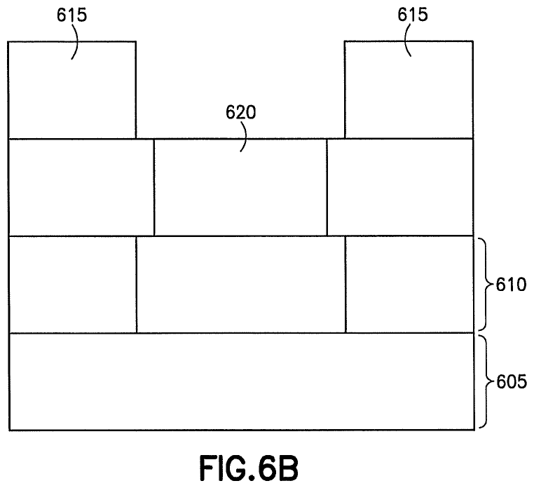

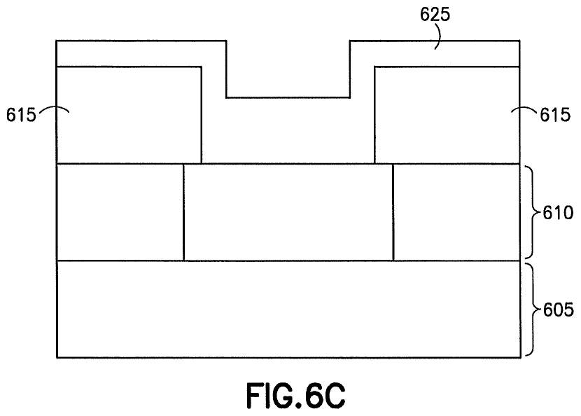

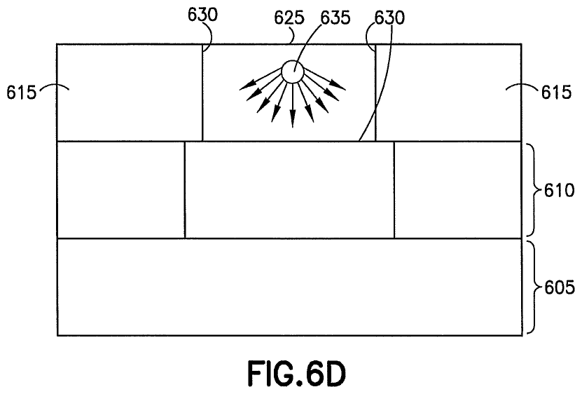

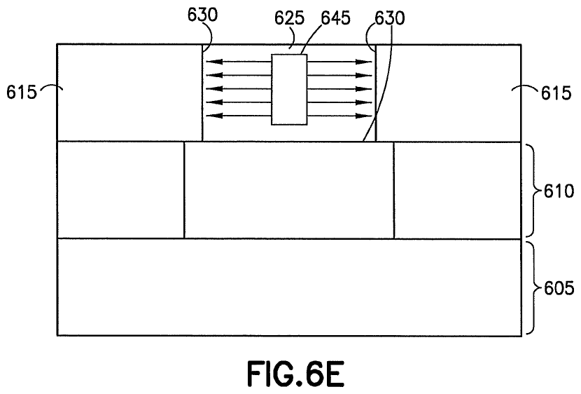

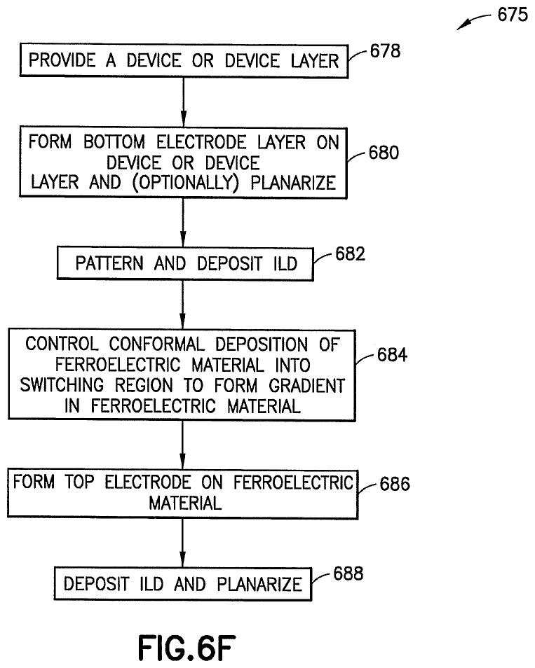

Referring now to FIGS. 6A through 6E, another example of a FeRAM structure incorporating a FeRAM cell 100 and a method of fabricating such a structure is shown. FIG. 6A shows the structure at 600. The method of fabrication uses a mask with a composition grading of a ferroelectric material 625. Gradients across the composition provide for the ferroelectric material 625 at one edge having a threshold switching electric field that is lower or higher than the threshold switching electric field of the ferroelectric material 625 at another edge or point. Gradients in composition are defined by a graded variation in concentration of at least one element from a point or area of a first concentration of the element to a point or area of a second concentration of the element. In this example method, a device or device layer 605 is provided and a bottom electrode layer 610 is formed as in the previous example methods. As shown in FIG. 6B, the bottom electrode layer 610 is patterned, and an ILD 615 is deposited around a switching region 620.

As shown in FIG. 6C, the ferroelectric material 625 is conformally deposited, using composition grading, onto upper surfaces of the ILD 615, inner side surfaces of the ILD 615 adjacent to the switching region 620, and onto the bottom electrode in the switching region 620.

As shown in FIG. 6D, the conformal deposition continues until the center portion of the ILD 615 over the switching region 620 is filled. In some example embodiments, the conformal deposition may be controlled such that peripheral edges 630 of the deposited ferroelectric material 625 have a higher concentration than a central point 635 of the deposited ferroelectric material 625 at an upper surface. The concentration gradients may progress from low concentrations at the central point 635 radially outward to high concentrations at the ILD 615 and at the bottom electrode layer 610. In other example embodiments, however, the conformal deposition may be controlled such that concentration at the central point 635 is higher than the concentrations at the peripheral edges 630.

As shown in FIG. 6E, the conformal deposition may be controlled to provide elongated vertical areas 645 of particular concentrations (versus the central point 635 of a particular concentration). In some examples, the vertical areas 645 may be of higher concentration than the peripheral edges 630 such that the concentration is graded in horizontal directions. In other examples, the vertical areas 645 may be of lower concentration than the peripheral edges 635. Planarization (such as CMP) may be carried out as needed.

In FIGS. 6A through 6E, the ferroelectric material 625 may be, for example, Hf(x)Zr(1-x)O₂. However, other materials may additionally or alternatively may be used.

Referring back to FIG. 6A, an upper ILD 665 is deposited, and a top electrode 670 is formed.

Referring now to FIG. 6F, a flow showing one example method of fabricating the FeRAM structure 600 is shown at 675 and is hereinafter referred to as “method 675.” In method 675, a device or device layer is provided as indicated at step 678. A bottom electrode layer is then formed on the device or device layer as indicated at step 680. Planarization (for example, CMP) may be carried out. As indicated at step 682, the upper (planarized) surface is patterned, and an ILD is deposited around a switching region designated as the area over the bottom electrode. As indicated at step 684, a conformal deposition of a ferroelectric material is controlled such that the ferroelectric material deposited on the bottom electrode layer has a gradient. Planarization may be carried out. As indicated at step 686, a top electrode is formed over the ferroelectric material. As indicated at step 688, an ILD may be formed around the top electrode, and a planarization may be carried out.

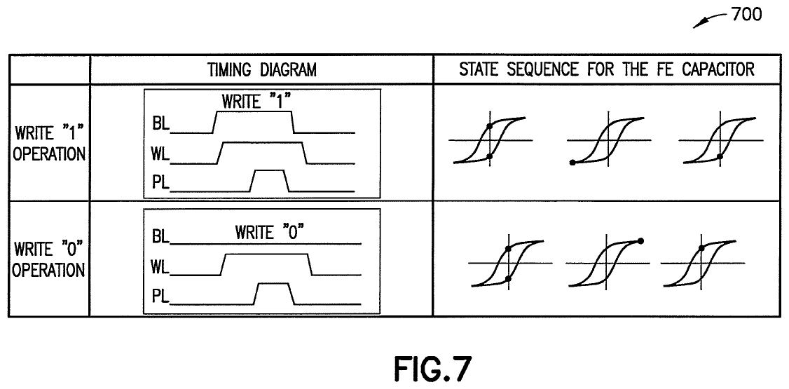

Referring now to FIG. 7, a chart or graphical representation (chart 700) of the FeRAM cell 100 shows respective timing diagrams, polarization states, and a state sequence of the cell over two WRITE operations, although it should be understood that more or less states are contemplated herein.

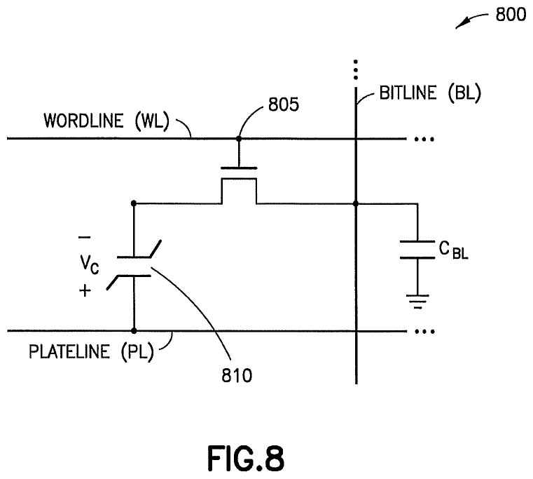

Referring now to FIG. 8, one example of a circuit incorporating a ferroelectric capacitor is shown generally at 800 and is hereinafter referred to as “circuit 800.” Circuit 800 is a 1T-1C (one transistor, one capacitor) memory cell. In the circuit 800, in a WRITE operation, when an access transistor 805 is “on,” a ferroelectric capacitor 810 (FE 810) in which the FeRAM cell 100 is incorporated is connected to a bitline BL and can be written to or read by a plateline PL. The total parasitic capacitance of the BL is represented by “C_{BL}.”

In a READ operation (a destructive READ operation), the BL is precharged to zero volts, and activating a wordline WL establishes a capacitor divider between the PL and a ground. Depending upon the data being stored, the FE 810 can be approximated by C0 or C1 (on or off capacitance) and thus the voltage may be with V0 or V1 (on or off). The PL is then raised to a power line V_{DD}. At this point, a sense amplifier is activated to drive the BL: if the BL is V1, then there is power from the power line V_{DD}; if the BL is V0, then there is 0 volts. The WL is maintained in an activated state until the sensed voltage on the BL restores the original data back into the memory cell.

Referring now to all the Figures, ferroelectric RAM has many applications. For example, FeRAM is non-volatile (contrast with the volatile memory of SRAM), has a fast write speed (in the nanosecond range) compared to other types of memory, has high read/write cycle endurance (in the teracycle range), and exhibits low power consumption compared to other memory. FeRAM also provides faster and more uniform switching of the FeRAM cell while maintaining retention time and reliability. Furthermore, FeRAM has overwrite ability (whereas EEPROM and Flash use erase and re-write). Additionally, unlike other types of memory, FeRAM does not require the use of a booster circuit.

FeRAM can be used as either standalone memory, or it can be used as an embedded large scale integration (FeRAM-embedded LSI) that is an application oriented LSI with FeRAM macros for RFID applications or authentications. FeRAM can be incorporated into counter equipment, parameter data storage equipment, in amusement, audio, and AV applications (for resume and parameter data storage), in measurement and medical applications, for logging management and cache memory, for tracing, and the like.

In one aspect, a ferroelectric random access memory cell comprises a ferroelectric active layer comprising a first ferroelectric material and at least one second ferroelectric material in contact with the first ferroelectric material; a first electrode in contact with the first ferroelectric material and the second ferroelectric material, the first electrode being positioned at a first side of the ferroelectric active layer; and a second electrode in contact with the first ferroelectric material and the second ferroelectric material, the second ferroelectric material being positioned at a second opposing side of the ferroelectric active layer. The first ferroelectric material has a threshold electric field for an intrinsic electric polarization reversal that is higher than the threshold electric field for an intrinsic electric polarization reversal of the second ferroelectric material. The first ferroelectric material at least partially surrounds the second ferroelectric material.

The first ferroelectric material may be positioned on opposing sides of the second ferroelectric material. The first ferroelectric material and the second ferroelectric material may be different. The first ferroelectric material and the second ferroelectric material may each be selected from the group consisting of Pb(Zr, Ti)O₃, BiFeO₃, BaTiO₃, and doped-hafnium oxide. The first ferroelectric material and the second ferroelectric material may be the same, and a concentration gradient of at least one element may exist between the first ferroelectric material and the second ferroelectric material. The doped-hafnium oxide may be doped with at least one of zirconium oxide, yttrium, silicon, aluminum, and lanthanum. Domains in the second ferroelectric material may reverse polarization before domains in the first ferroelectric material and provide nucleation points for the intrinsic electric polarization reversal of the domains in the first ferroelectric material.

In another aspect, a ferroelectric random access memory cell comprises an active layer comprising a ferroelectric material having a concentration gradient with regard to at least one element in the active layer; and a first electrode and a second electrode in contact with the ferroelectric material, the first electrode being positioned at a first side of the active layer and the second electrode being positioned at a second side of the active layer. A first portion of the ferroelectric material has a threshold electric field for an intrinsic electric polarization reversal that is higher than a threshold electric field for an intrinsic electric polarization reversal E a second portion of the ferroelectric material.

The first portion of the ferroelectric material may comprise a first concentration of the at least one element at a central point and the second portion of the ferroelectric material may comprise a second concentration of the at least one element at edges of the ferroelectric material such that the concentration gradient extends radially from the central point. The first concentration of the at least one element may be less than the second concentration of the at least one element. The first concentration of the at least one element may be greater than the second concentration of the at least one element. The first portion of the ferroelectric material may comprise a first concentration of the at least one element at an elongated area extending vertically through a center area of the ferroelectric material and the second portion of the ferroelectric material may comprise a second concentration of the at least one element at edges of the ferroelectric material such that the concentration gradient extends horizontally from the elongated area. The first concentration of the at least one element may be less than the second concentration of the at least one element. The first concentration of the at least one element may be greater than the second concentration of the at least one element.

In another aspect, a method of forming a ferroelectric random access memory cell comprises forming a bottom electrode on a device layer; depositing a first ferroelectric material on the bottom electrode; depositing a second ferroelectric material within the first ferroelectric material; and forming a top electrode on the first ferroelectric material and the second ferroelectric material. The first ferroelectric material has a higher threshold electric field value for an intrinsic electric polarization reversal than the second ferroelectric material.

The method may further comprise depositing interlayer dielectric materials around the bottom electrode, the first ferroelectric material, and the top electrode. The method may further comprise performing a recrystallization anneal after depositing the second ferroelectric material. The method may further comprise recessing a center portion of the first ferroelectric material before depositing the second ferroelectric material. Depositing the second ferroelectric material within the first ferroelectric material may comprise depositing the second ferroelectric material within the recessed center portion. Depositing the first ferroelectric material on the bottom electrode may comprise depositing the first ferroelectric material and patterning and etching the deposited first ferroelectric material to form a ring structure.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A ferroelectric random access memory cell, comprising:
a ferroelectric active layer comprising a first ferroelectric material and at least one second ferroelectric material in contact with the first ferroelectric material;
a first electrode in contact with the first ferroelectric material and the second ferroelectric material, the first electrode being positioned at a first side of the ferroelectric active layer; and
a second electrode in contact with the first ferroelectric material and the second ferroelectric material, the second ferroelectric material being positioned at a second opposing side of the ferroelectric active layer;
wherein the first ferroelectric material has a threshold electric field for an intrinsic electric polarization reversal that is higher than the threshold electric field for an intrinsic electric polarization reversal of the second ferroelectric material; and
wherein the first ferroelectric material at least partially surrounds the second ferroelectric material.

2. The ferroelectric random access memory cell of claim 1, wherein the first ferroelectric material is positioned on opposing sides of the second ferroelectric material.

3. The ferroelectric random access memory cell of claim 1, wherein the first ferroelectric material and the second ferroelectric material are different.

4. The ferroelectric random access memory cell of claim 1, wherein the first ferroelectric material and the second ferroelectric material are each selected from the group consisting of Pb(Zr, Ti)O₃, BiFeO₃, BaTiO₃, and doped-hafnium oxide.

5. The ferroelectric random access memory cell of claim 4, wherein the first ferroelectric material and the second ferroelectric material are the same, and wherein a concentration gradient of at least one element exists between the first ferroelectric material and the second ferroelectric material.

6. The ferroelectric random access memory cell of claim 4, wherein the doped-hafnium oxide is doped with at least one of zirconium oxide, yttrium, silicon, aluminum, and lanthanum.

7. The ferroelectric random access memory cell of claim 1, wherein domains in the second ferroelectric material reverse polarization before domains in the first ferroelectric material and provide nucleation points for the intrinsic electric polarization reversal of the domains in the first ferroelectric material.

8. A ferroelectric random access memory cell, comprising:
an active layer comprising a ferroelectric material having a concentration gradient with regard to at least one element in the active layer; and
a first electrode and a second electrode in contact with the ferroelectric material, the first electrode being positioned at a first side of the active layer and the second electrode being positioned at a second side of the active layer;
wherein a first portion of the ferroelectric material has a threshold electric field for an intrinsic electric polarization reversal that is higher than a threshold electric field for an intrinsic electric polarization reversal of a second portion of the ferroelectric material.

9. The ferroelectric random access memory cell of claim 8, wherein the first portion of the ferroelectric material comprises a first concentration of the at least one element at a central point and the second portion of the ferroelectric material comprises a second concentration of the at least one element at edges of the ferroelectric material such that the concentration gradient extends radially from the central point.

10. The ferroelectric random access memory cell of claim 9, wherein the first concentration of the at least one element is less than the second concentration of the at least one element.

11. The ferroelectric random access memory cell of claim 9, wherein the first concentration of the at least one element is greater than the second concentration of the at least one element.

12. The ferroelectric random access memory cell of claim 8, wherein the first portion of the ferroelectric material comprises a first concentration of the at least one element at an elongated area extending vertically through a center area of the ferroelectric material and the second portion of the ferroelectric material comprises a second concentration of the at least one element at edges of the ferroelectric material such that the concentration gradient extends horizontally from the elongated area.

13. The ferroelectric random access memory cell of claim 12, wherein the first concentration of the at least one element is less than the second concentration of the at least one element.

14. The ferroelectric random access memory cell of claim 12, wherein the first concentration of the at least one element is greater than the second concentration of the at least one element.

15. A method of forming a ferroelectric random access memory cell, comprising:
forming a bottom electrode on a device layer;
depositing a first ferroelectric material on the bottom electrode;
depositing a second ferroelectric material within the first ferroelectric material; and
forming a top electrode on the first ferroelectric material and the second ferroelectric material;
wherein the first ferroelectric material has a higher threshold electric field value for an intrinsic electric polarization reversal than the second ferroelectric material.

16. The method of claim 15, further comprising depositing interlayer dielectric materials around the bottom electrode, the first ferroelectric material, and the top electrode.

17. The method of claim 15, further comprising performing a recrystallization anneal after depositing the second ferroelectric material.

18. The method of claim 15, further comprising recessing a center portion of the first ferroelectric material before depositing the second ferroelectric material.

19. The method of claim 15, wherein depositing the second ferroelectric material within the first ferroelectric material comprises depositing the second ferroelectric material within the recessed center portion.

20. The method of claim 15, wherein depositing the first ferroelectric material on the bottom electrode comprises depositing the first ferroelectric material and patterning and etching the deposited first ferroelectric material to form a ring structure.
